(19) United States
(12) Patent Application Publication
(10) Pub. No.: US 2009/0233413 A1
(43) Pub. Date: Sep. 17, 2009

(54) Method for fabricating semiconductor device

(75) Inventor: Takeshi Katayama, Ibaraki (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/382,074

(22) Filed: Mar. 9, 2009

(30) Foreign Application Priority Data
Mar. 11, 2008 (JP) 2008-060580

(51) Int. Cl. H01L 21/762; H01L 21/26

(52) U.S. Cl. 438/400; 438/795; 257/E21.545; 257/E21.328

(57) ABSTRACT

A method for fabricating a semiconductor device using a SOI substrate, includes the steps of: preparing a SOI substrate, comprises a semiconductor support layer; an insulating layer formed on the semiconductor support layer; and a SOI layer formed on the insulating layer; forming an active region on the SOI layer, so that a part of the semiconductor support layer is exposed; and forming a specific mark on the exposed part of the semiconductor support layer.

### CROSS REFERENCE TO RELATED APPLICATION

This application claims the priority of Application No. 2008-060580, filed Mar. 11, 2008 in Japan, the subject matter of which is incorporated herein by reference.

### TECHNICAL FIELD OF THE INVENTION

The present invention relates to a method for fabricating a semiconductor device using a SOI (Silicon-On-Insulator) substrate.

### BACKGROUND OF THE INVENTION

Recently, an SOI substrate has been used widely for a semiconductor device. An SOI substrate has a variety of advantages as compared with a bulk silicon substrate. An SOI substrate includes a semiconductor support layer; an insulating layer (BOX layer) formed on the semiconductor support layer; and an SOI layer (silicon layer) formed on the insulating layer. In fabrication process of a semiconductor device, LOCOS (Local Oxidation of Silicon) technique and STI (Shallow Trench Isolation) technique are well know as a device isolation technique.

FIGS. 1A to 1H are cross sectional views showing fabrication process of a semiconductor device according to a conventional method. First, as shown in FIG. 1A, an SOI substrate is prepared. The SOI substrate includes a semiconductor support layer 101; an insulating layer (BOX layer) 102 formed on the semiconductor support layer 101; and an SOI layer (silicon layer) 104 formed on the insulating layer.

Next, as shown in FIG. 1B, a part of the SOI layer 104 and BOX layer 102 is removed by a lithography and etching process to form a specific region to be used for forming a wafer ID thereon After that, as shown in FIG. 1C, a wafer ID 106 is formed on the exposed region of the semiconductor support layer 101 by a laser-marking technique. In order to avoid undesirable dust or coarse particulates, the SOI layer 104 and BOX layer 102 are partly removed.

The following patent publications describe a method for forming a wafer ID on a semiconductor substrate;
[Patent Publication 1] JP2002-33250A
[Patent Publication 2] JP2005-72027A

Next, as shown in FIG. 1D, a Si nitride layer 108 is formed on a surface of the wafer entirely. The Si nitride layer 108 is used as a stopper layer in a following flattening process.

Next, a resist layer (110) is formed on the Si nitride layer 108, and then the resist layer 110 is patterned, as shown in FIG. 1E, so that the resist layer 110 remains at regions corresponding to later-formed active regions.

Subsequently, lithography and etching process is carried out to pattern (shape) active regions 104 using the resist layer 110 as a mask, as shown in FIG. 1F. In this process, the box layer 102 is removed from a region on the wafer ID 106 to expose the wafer ID 106.

Next, as shown in FIG. 1G, an oxide layer 112 is formed on the wafer entirely.

Next, as shown in FIG. 1H, a CMP process is carried out to remove the Si nitride layer 108 to form a STI region (112) and to flatten the surface of the wafer. After that, the semiconductor support layer 101 is exposed at a region where an alignment mark (not shown) is formed.

According to the above described conventional method, lithography and etching process is required only in order to remove the SOI layer 104 and the BOX layer 102 located above the wafer ID. As a result, more process is necessary, and more masks are necessary to use, and as a result, fabrication cost would increase.

In general, according to a STI technique for forming a device isolation region, there is an advantage in that an active region and a device isolation region are formed to be flat. On the other hand, there is a disadvantage in that an alignment mark used in a lithography process is hardly recognized or detected, and therefore, a specific process for exposing an alignment mark on the wafer is required.

### OBJECTS OF THE INVENTION

Accordingly, an object of the present invention is to provide a method for fabricating a semiconductor device, which may reduce the number of process for forming a wafer ID and reduce the number of masks to be used.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a method for fabricating a semiconductor device using a SOI substrate, includes the steps of: preparing a SOI substrate, comprises a semiconductor support layer; an insulating layer formed on the semiconductor support layer; and a SOI layer formed on the insulating layer; forming an active region on the SOI layer, so that a part of the semiconductor support layer is exposed; and forming a specific mark on the exposed part of the semiconductor support layer. Here, “a specific mark” includes a wafer ID.

According to a second aspect of the present invention, a method for fabricating a semiconductor device using a SOI substrate, includes the steps of preparing a SOI substrate, including a semiconductor support layer, an insulating layer formed on the semiconductor support layer, and a SOI layer formed on the insulating layer; forming an active region on the SOI layer; forming a device isolation regions around the active region; removing a part of the device isolation region to expose a part of the semiconductor support layer; and forming a specific mark on the exposed part of the semiconductor support layer.

Preferably, in the method according to the second aspect of the present invention, a method further includes the steps of: forming an alignment mark on the semiconductor support layer prior to forming the device isolation region; and removing a part of the device isolation region to expose the alignment mark and a region for forming the specific mark at the same time. According to the second aspect of the present invention, a step of lithography and etching for removing an SOI layer and BOX layer only to form a specific mark can be omitted. As a result, the number of process for exposing an alignment mark may be reduced.

### BRIEF DESCRIPTION OF THE DRAWINGS

FIGS. 1A-1H are cross-sectional views sowing fabrication process according to a conventional method for fabricating a semiconductor device.

FIGS. 2A-3G are cross-sectional views sowing fabrication process in a method for fabricating a semiconductor device according to a first preferred embodiment of the present invention.

FIGS. 3A-3H are cross-sectional views sowing fabrication process in a method for fabricating a semiconductor device according to a second preferred embodiment of the present invention.

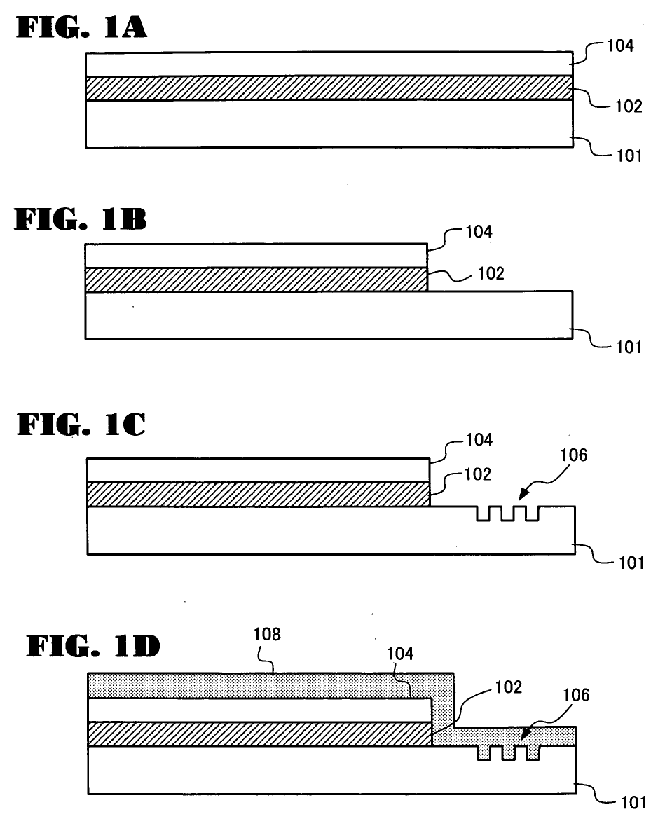

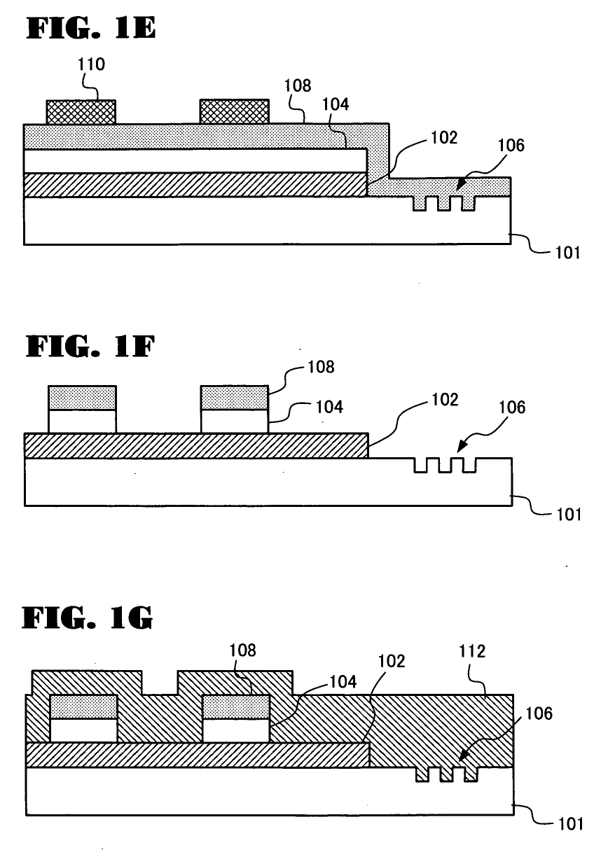

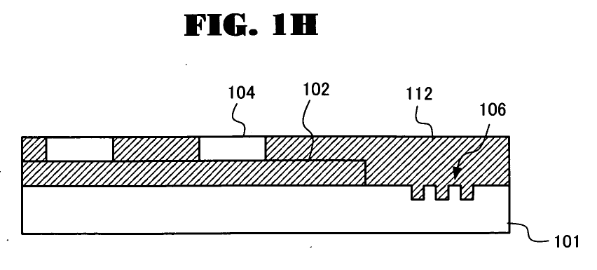

### DESCRIPTION OF REFERENCE NUMERALS

201, 301: Semiconductor Support layer

202, 302: BOX Layer

204, 304: SOI Layer

206, 306: Wafer ID

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

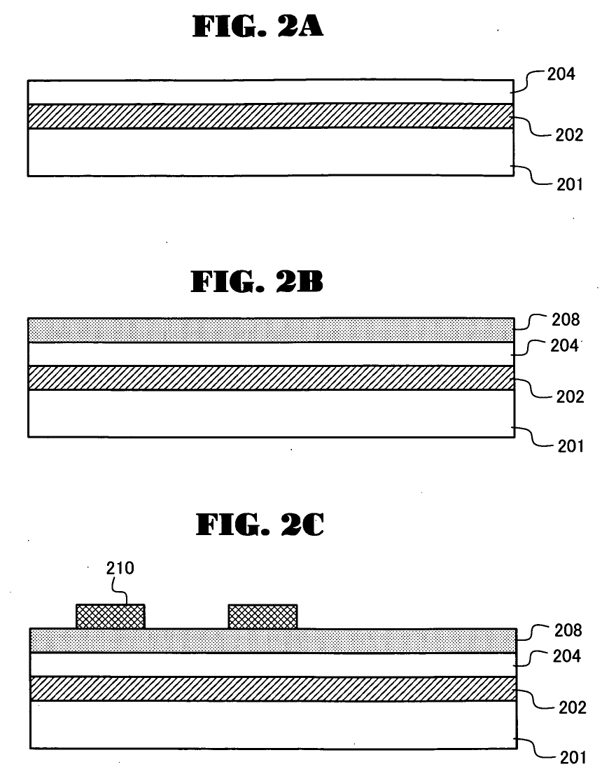

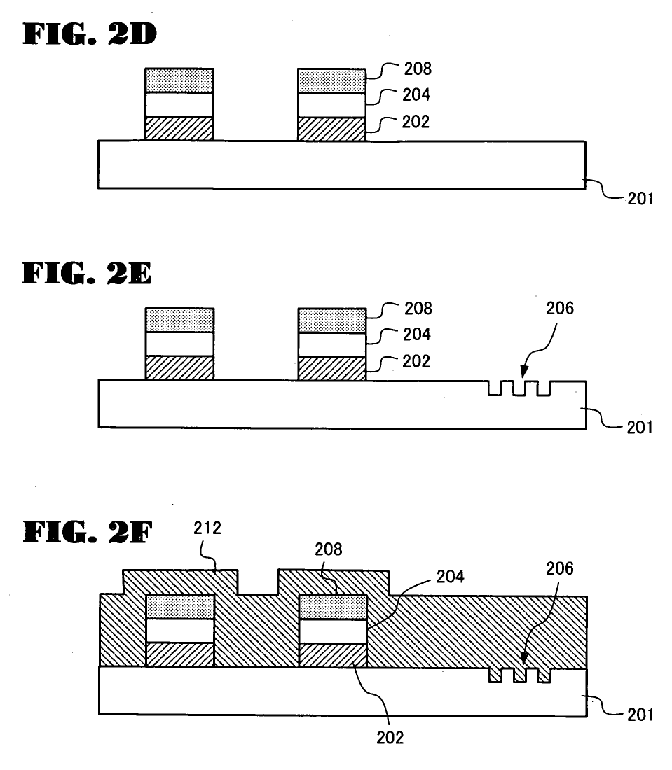

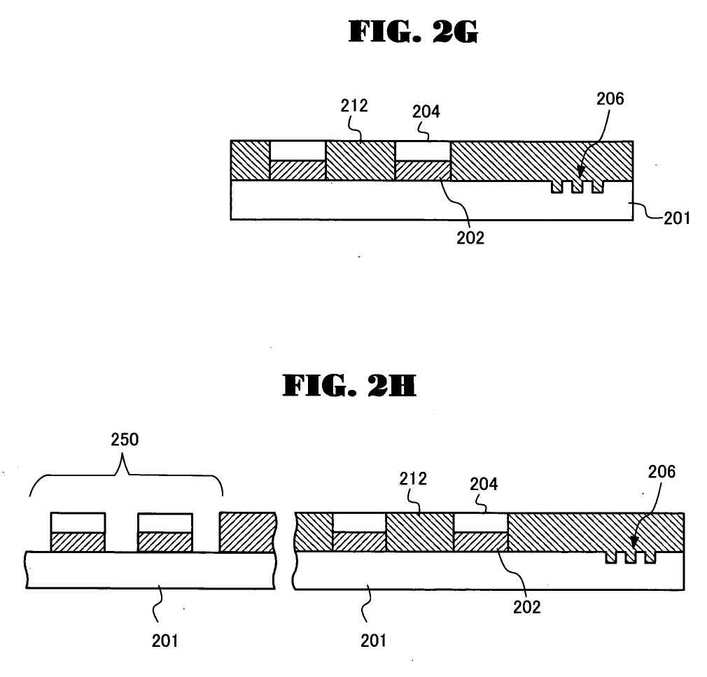

FIGS. 2A-2H are cross-sectional views sowing fabrication process in a method for fabricating a semiconductor device according to a first preferred embodiment of the present invention. According to the above-described conventional method, at an early stage of wafer process, a SOI layer and a BOX layer are removed to expose a region to form a wafer ID, and then, a laser marking process is carried out to form the wafer ID. On the other hand, according to the present embodiment, prior to forming a wafer ID, a SiN layer (208) is formed.

First, as shown in FIG. 2A, an SOI substrate is prepared. The SOI substrate includes a semiconductor support layer 201; an insulating layer (BOX layer) 202 formed on the semiconductor support layer 201; and an SOI layer (silicon layer) 204 formed on the insulating layer.

Next, as shown in FIG. 2B, a Si nitride layer 208 is formed on the SOI layer 204. The Si nitride layer 208 is to be used as a stopper layer in a CMP process.

Next, a resist layer (210) is formed on the Si nitride layer 208, and then the resist layer 210 is patterned, as shown in FIG. 2C, so that the resist layer 210 remains at regions corresponding to later-formed active regions.

Subsequently, lithography and etching process is carried out to pattern (shape) active regions 204 using the resist layer 210 as a mask, as shown in FIG. 2D. In this process, the box layer 202 is also removed to expose a part of the semiconductor support layer 201 from a region where a wafer ID 206 is to be formed.

After that, as sown in FIG. 2E, a wafer ID 206 is formed on the exposed region of the semiconductor support layer 201 by a laser-marking technique. In order to avoid undesirable dust or coarse particulates, the SOI layer 204 and BOX layer 202 are partly removed.

Next, as shown in FIG. 2F, an oxide layer 212 is formed on the wafer entirely.

Next, as shown in FIG. 2G, a CMP process is carried out to remove the Si nitride layer 208 to form a STI region (212) and to flatten the surface of the wafer.

After that, as shown in FIG. 2H, the semiconductor support layer 201 is exposed at a region where an alignment mark 250 is formed.

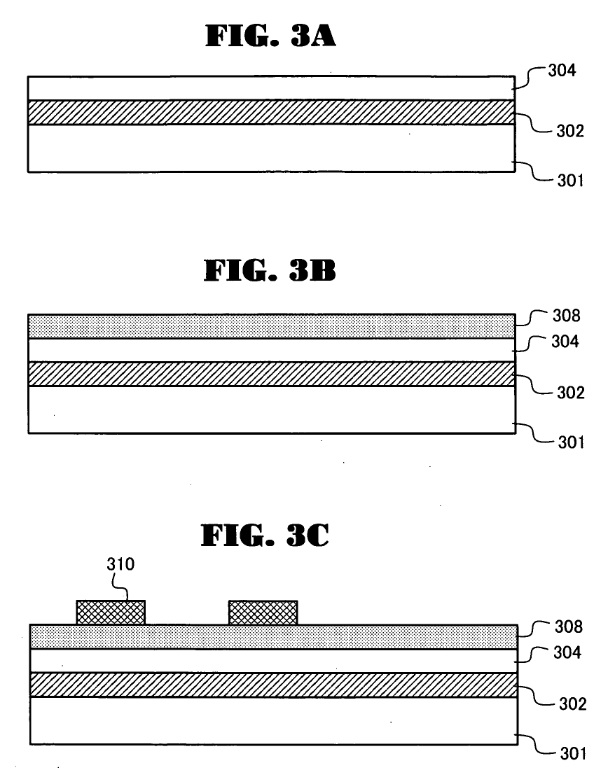

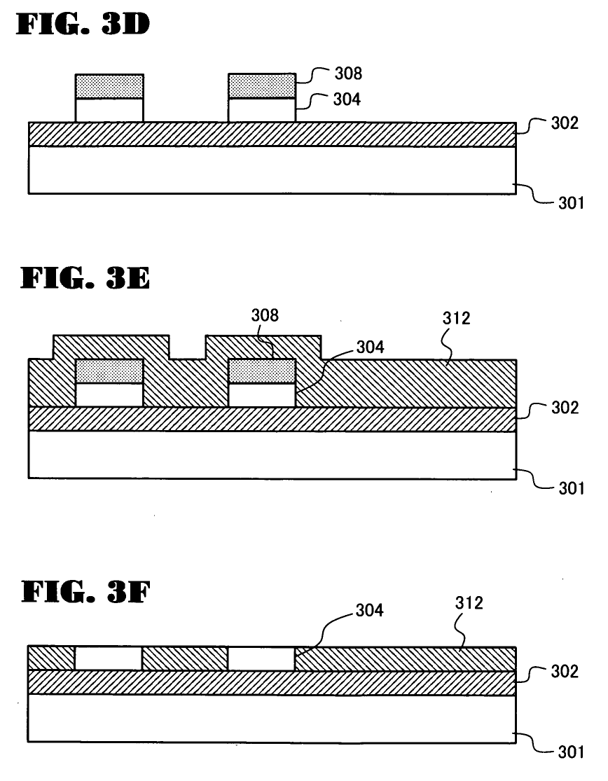

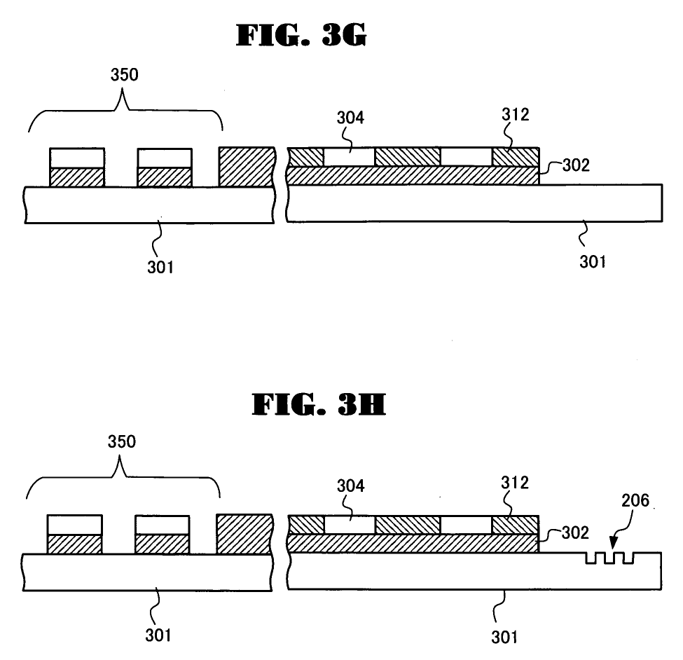

FIGS. 3A-3H are cross-sectional views sowing fabrication process in a method for fabricating a semiconductor device according to a second preferred embodiment of the present invention. According to the present embodiment, a BOX layer is removed both for exposing an alignment mark and for exposing a region to be used for forming a wafer ID, so that fabrication process could be simplified. According to the conventional method, prior to forming a device isolation region, an SOI layer and BOX layer are removed from a region to be used for forming a wafer ID. On the other hand, according to the present embodiment, after forming a device isolation region, an alignment mark is exposed. In the same process for exposing the alignment mark, a BOX layer and the device isolation region are removed from a region to be used for forming a wafer ID.

First, as shown in FIG. 3A, an SOI substrate is prepared. The SOI substrate includes a semiconductor support layer 301; an insulating layer (BOX layer) 302 formed on the semiconductor support layer 301; and an SOI layer (silicon layer) 304 formed on the insulating layer.

Next, as shown in FIG. 3B, a Si nitride layer 308 is formed on the SOI layer 304. The Si nitride layer 308 is to be used as a stopper layer in a CMP process.

Next, a resist layer (310) is formed on the Si nitride layer 308, and then the resist layer 310 is patterned, as shown in FIG. 3C, so that the resist layer 310 remains at regions corresponding to later-formed active regions.

Subsequently, lithography and etching process is carried out to pattern (shape) active regions 304 using the resist layer 310 as a mask, as shown in FIG. 3D. In this process, the box layer 302 is not removed not to expose the semiconductor support layer 301.

Next, as shown in FIG. 3E, an oxide layer 312 is formed on the wafer entirely.

Next, as shown in FIG. 3F, a CMP process is carried out to remove the Si nitride layer 308 to form a STI region (312) and to flatten the surface of the wafer.

Subsequently, as shown in FIG. 3G, the BOX layer 302 and the oxide layer (device isolation region) 312 are removed to expose a region on the semiconductor support layer 301 to be used for forming a wafer ID. At the same time, the BOX layer 302 and the oxide layer (device isolation region) 312 are removed to expose a region where an alignment mark 350 has been formed to expose the mark.

After that, as sown in FIG. 3H, a wafer ID 206 is formed on the exposed region of the semiconductor support layer 301 by a laser-marking technique.

What is claimed is:

1. A method for fabricating a semiconductor device using a SOI substrate, comprising:
preparing a SOI substrate, which includes a semiconductor support layer, an insulating layer formed on the semiconductor support layer, and a SOI layer formed on the insulating layer;
forming an active region on the SOI layer so that a part of the semiconductor support layer is exposed; and
forming a specific mark on the exposed part of the semiconductor support layer.

2. A method for fabricating a semiconductor device using a SOI substrate according to claim 1, wherein
the specific mark is a wafer identification mark.

3. A method for fabricating a semiconductor device using a S01 substrate according to claim 1, further comprising:
forming an insulating layer over the substrate entirely after the specific mark has been formed; and
removing a surface of the insulating layer on the substrate so as to form a device isolation region.

4. A method for fabricating a semiconductor device using a SOI substrate according to claim 1, wherein
said specific mark is formed by irradiating a laser beam to the semiconductor support layer.

5. A method for fabricating a semiconductor device using a SOI substrate, comprising:
preparing a SOI substrate, which comprises a semiconductor support layer, an insulating layer formed on the semiconductor support layer, and a SOI layer formed on the insulating layer;
forming an active region on the SOI layer;
forming a device isolation regions around the active region;
removing a part of the device isolation region to expose a part of the semiconductor support layer; and
forming a specific mark on the exposed part of the semiconductor support layer.

6. A method for fabricating a semiconductor device using a SOI substrate according to claim 5, wherein
the specific mark is a wafer identification mark.

7. A method for fabricating a semiconductor device using a SOI substrate according to claim 5, further comprising:
forming an alignment mark on the semiconductor support layer prior to forming the device isolation region; and
removing a part of the device isolation region to expose the alignment mark and a region for forming the specific mark at the same time.

8. A method for fabricating a semiconductor device using a SOI substrate according to claim 5, wherein
said specific mark is formed by irradiating a laser beam to the semiconductor support layer.
